(19) United States
(12) Patent Application Publication
(10) Pub. No.: US 2014/0035610 A1
(43) Pub. Date: Feb. 6, 2014

(54) SYSTEM AND METHOD TO TEST A SEMICONDUCTOR POWER SWITCH

(71) Applicant: Patrick Heringer, Sainte Livrade (FR)

(72) Inventor: Patrick Heringer, Sainte Livrade (FR)

(73) Assignee: FREESCALE SEMICONDUCTOR INC., Austin, TX (US)

(21) Appl. No.: 14/110,877

(22) PCT Filed: Apr. 19, 2012
(86) PCT No.: PCT/IB2012/001431

§ 371 Date: Oct. 9, 2013

(30) Foreign Application Priority Data
Apr. 21, 2011 (IB) PCT/IB2011/001215

(51) Int. Cl. G01R 1/04

(52) U.S. Cl. CPC G01R 1/0441
USPC 324/756.02

(57) ABSTRACT

Testing assembly for testing a singulated semiconductor die comprising a power component. The assembly comprises an current input connectable to a current source, for providing a current greater than 50 Amps to the power component; a signal output connectable to a signal analyzer, for receiving signals representing a sensed parameter of the power component sensed when the current is provided; a first contact unit, adapted to support the semiconductor die; a second contact unit, movably mounted relative to the first contact unit; and at least an electrically-conductive resilient sheath, adapted to be sandwiched between the semiconductor die and the second contact unit when the second contact unit is brought toward the semiconductor die during a test, the sheath forming part of an electrical path from the current input through at least a part of the die when thus sandwiched.

### FIELD OF THE INVENTION

This invention relates to a test assembly and a method to testing singulated semiconductor dies comprising a high-power component.

### BACKGROUND OF THE INVENTION

Testing of semiconductor high-power components is a challenging task. The reliability and consistency of the test depend on the amount of current that flows through the die, more particularly (for dies comprising a power Field Effect Transistor (FET)) from the drain terminal to the source terminal. The reliability and consistency further depend on the duration of the power pulse during the test.

In known techniques to test singulated semiconductor dies, movable probes comprising a barrel which houses a micro spring connecting a plunger and a contact point, also known as ‘pogos’, are used which are brought in physical contact with e.g. a source terminal of the power component in order to inject the desired current. The physical contact is required to sustain the high amount of current but this physical contact can damage the surface of the semiconductor die.

The use of an electrically-conductive compliant elastomer between a die and test terminals is known from U.S. Pat. No. 5,672,979. However, this elastomer is anisotropically conductive, meaning that when it is compressed, it conducts only in the direction of the compression.

### SUMMARY OF THE INVENTION

The present invention provides a testing assembly and a method as described in the accompanying claims.

Specific embodiments of the invention are set forth in the dependent claims.

These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings. In the drawings, like reference numbers are used to identify like or functionally similar elements. Elements in the figures are illustrated for simplicity and clarity and have not necessarily been drawn to scale.

FIG. 1 schematically shows a block diagram of an example of an embodiment of a test assembly,

FIG. 2 schematically shows a perspective view of an example of an embodiment of a contactor suitable for the example of FIG. 1.

FIG. 3 schematically shows a partial exploded view of the contactor of FIG. 2,

FIG. 4 schematically shows a cross section of the contactor of FIG. 2, taken along line IV-V of FIG. 3,

FIG. 5 schematically shows a cross section of another example of a contactor.

FIG. 6 shows a flow chart of an example of a method for testing a singulated semiconductor die.

### DETAILED DESCRIPTION OF THE PREFERRED EMBODIMENTS

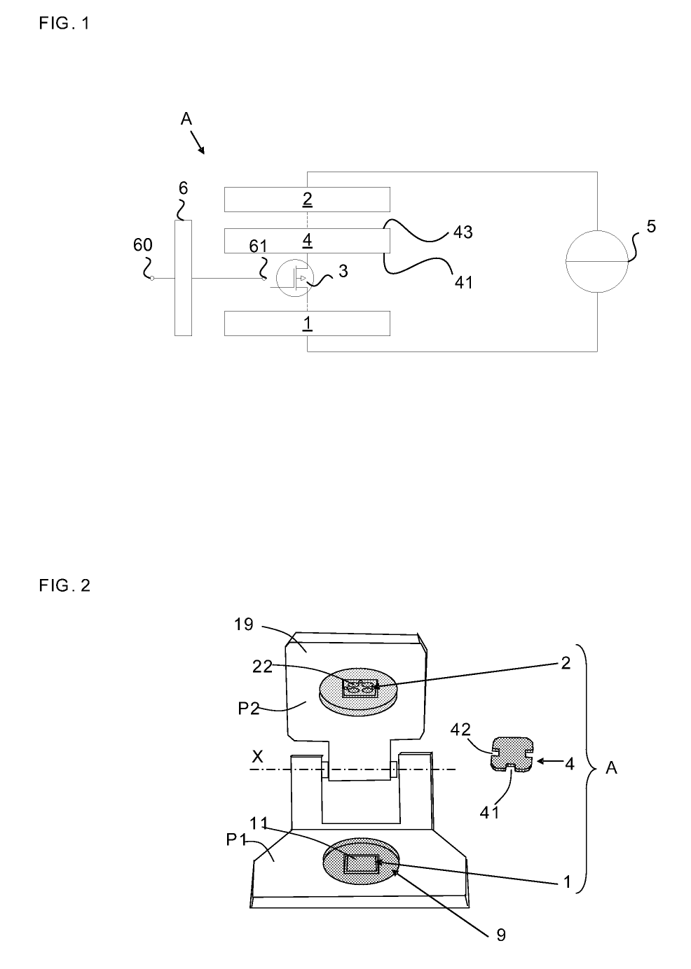

FIG. 1 shows an example of an embodiment of a testing assembly A. The shown example comprises an input connectable to a high-current current source 5 and a signal output 60 connectable to a signal analyzer. Via the input, high current can be provided to the power component. Though the output, signals can be received by the signal analyzer which represent a sensed parameter of the power component sensed when the current is provided.

The shown example further comprises a contactor with a first contact unit 1 adapted to support a singulated semiconductor die 3 during the test. The die 3 comprises a high-power component to be tested, The contactor further comprises a second contact unit 2, movably mounted relative to the first contact unit 1. The testing assembly A further comprises an electrically-conductive resilient sheath 4, adapted to be sandwiched between the semiconductor die 3 and the second contact unit 2, as it will be explained later, when the second contact unit 2 is brought toward the semiconductor die 3.

When sandwiched, the sheath 4 forms part of an electrical path from the input through at least a part of the die 3 while protecting the contact-surface of the die. When sandwiched, the sheath 4 deforms resiliently and thus absorbs at least a part of the pressure exerted by the contact unit 2 on the die 3, thus reducing the risk of physical deformation of parts of the die 3 and accordingly of damage to the die. The sheath 4 further disperses the current provided by the current supply over its surface, thereby avoiding peak current locations with an excessive current density on the surface of the die 3.

Physical contact with conventional ‘pogos’ is known to create surface imprints of several microns, which can cause problems during later bonding. Providing a resilient sheath 4 may reduce the occurrence and depth of such imprints. Additionally, the resilient sheath 4 may also improve the lifetime of the ‘pogos’ that repeatedly have to make contact when a plurality of dies 3 are tested.

The die 3 may be any type of die in need of being tested. In the shown example, the die 3 is a singulated bare die. However the die may be provided in a housing, for example, which leaves the surface to be brought in contact with the sheath 4 exposed to the outside. The die 3 comprises a high-power component, in this example a power Field Effect Transistor (FET) operating as a power switch. The die 3 may however comprise types of high-power components other than switches, such as diodes, amplifiers etc. and may also comprise semiconductor devices other than a FET, such as for example an Insulated Gate Bipolar Transistor (IGBT), a Bipolar Junction Transistor, a High Electron Mobility Transistor, a thyristor or other suitable semiconductor device. Components are considered to be high-power if they require a high current (50 Amps or more) to test.

The testing assembly A may be implemented in any manner suitable for the specific implementation. For example, as tester such a commercial available tester may be used, such as one of the following:

Flex or uFlex with a PVI300 module sold by Teradyne, Inc of North Reading, Mass. United States,

MST with 4PG as sold by Telco Testing Solutions, LLC of Tempe, Ariz. United States

430 or 600 series with IPS instrument as sold by SPEA S.p.A. of Volpiano (TO), Italy.

The testing assembly may use a commercially available contactor such as manufactured by Ismeca Semiconductor of La Chaux-de-Fonds, Switzerland.

In the example of FIG. 1, the high-current current source 5 is connected to the first and second contact unit 1,2 such that during test a current path is formed from the current source 5 through the first contact 1, at least a part of the die 3, the protective sheath 4 and through the second contact unit 2. In this example, during test the second contact unit 2 is physically in contact with a first surface 43 of the electrically-conductive sheath 4, thus establishing an electrically-conducting contact between the unit and the sheath. A second surface 44 of the sheath 4 is physically in contact with the die 3 during test, thus establishing an electrically-conducting contact between the sheath 4 and the die 3. During test, the die 3 in turn is in physical contact with the first contact unit 1, thus establishing an electrically-conducting contact between the first contact unit 1 and the die 3.

The electrically-conductive resilient protective sheath 4 may be implemented in any manner suitable for the specific implementation and be made of any suitable material. The sheath 4 may have any suitable shape, such as circular, square etc, and size. In the shown example, the protective sheath is provided with a first cut-out 41 and at least an additional cut-out 42 whose function will be explained below. The sheath 4 may have any suitable thickness. The sheath 4 may e.g. have a thickness of at least 0.1 mm and/or less than 2 mm, such as 0.2 mm for example.

The sheath 4 may have any suitable size, and for example have a surface equivalent r that is larger than the contact-surface of the second contact unit 2. Thereby, it can be ensured that any current provided through the contact unit 2 passes through the protective sheath 4, and that there is no direct physical contact pressure by the contact unit 2 on the die 3.

In addition, the sheath 4 may have an electrical contact-surface with the die 3 which is larger than the electrical contact-surface with the second contact unit 2—this spreads the current as uniform as possible, to reduce the risk of arcing due to peak current locations and excessive current densities.

The protective sheath 4 may for instance be made of a material which exhibits thermal properties, like a high temperature tolerance, by withstanding a permanent temperature of a least 125° C. and peak temperature of at least 150° C., preferably 180° C., and a sufficient thermal conductivity that helps evacuating Joule effect energy produced during the test.

For example, the protective sheath 4 may be made of an electrically-conductive elastomer. The sheath 4 can e.g. be is a thin sheet made of elastomeric material loaded metallic or other conductive particles, such as steel and/or copper particles in order to exhibit a good electrical conductivity. A suitable material has found to be a silicon based elastomer with silver plated copper particles, such as sold by Getelec of Buc with product reference GT1000.

Anisotropically conductive elastomers are known in the art, for example in U.S. Pat. No. 5,672,979, but they are inherently unsuitable for use as the electrically-conductive resilient sheath 4. They require pressure to be conductive, and are typically used only for the connection of signals. To keep heating to minimum, the IR drop in the electrical path should be kept as low as possible—this means that if an anisotropically conductive elastomer was used for high-current testing, a very high pressure would be needed to reduce the heating, but increasing the pressure increases the risk of damage to the die contact-surfaces. Additionally, the current flowing through an anisotropically conductive elastomer is confined within the region under pressure, increasing the risk of peak current locations and excessive current densities.

The protective sheath 4 may have a high conductance when a low pressure is asserted, or may have a conductivity that is unaffected by pressure. It may be advantageous to select a material that allows current to flow in either direction so that the same sheath 4 may be used for different types of high-power component, for example either P-type or N-type.

It may be a mono or multilayer material, for example a laminate of multiple layers of different constitution. Also, multiple protective sheaths may be stacked and interposed between the die surface and first and/or second contact unit. The sheath 4 may comprise a metallic mesh or a metallic grid embedded in an elastic material in such a manner that at both sides of the sheet at least a part of the mesh grid is exposed and an conductive contact between both side is present, whilst the elastic material absorbs pressure exerted on the sheet surface. Also, for example, the protective sheath 4 may be made of an elastic conductive polymer. Also, the protective sheath may be a sheet of one or more layers of elastic material, e.g. rubber, with thin metal wires extending between the two surfaces of the sheet. The skilled person will realise that the sheath may be implemented in any other suitable manner consistent with the required electrical conductivity and resilience.

Furthermore, the sheath 4 may be provided with the die and be packaged together, for example to protect the die when bond wires are provided on the die. Accordingly, the sheath 4 may be part of an assembly which comprises the die, and subsequently be packaged and is desired permanently fixated relative to the die and/or the housing in which the die and sheath 4 are packaged.

The contactor may be implemented in any manner suitable for the specific implementation. Although in this description, the term “contactor” is used to refer to a part of the testing assembly, for convenience, it will be apparent that the parts thereof may form an integral part of the testing assembly. Referring to FIG. 2, the example of a contactor shown therein comprises a first contact unit 1 and a second contact unit 2. The die 3 is not shown in FIG. 2. When starting a test, the first contact and second contact are moved towards each other, with the protective sheath 4 positioned between the die and the second contact unit 2, such that the above explained physical contacts are established and the sheath 4 is sandwiched between the second contact unit 2 and the die.

Once the electrical path is established, high current can be sent through the die via the current path and parameter of the die can be observed. In the example of FIG. 1, the testing assembly comprises a sensor 6 with a sensor input 61 positioned such that the desired parameter of the die 3 can be sensed. The sensor 6 is connected to the output 60 in order to allow a signal analyzer to receive signals representing the sensed parameter, such as temperature, voltage drop over parts of the die, etc.

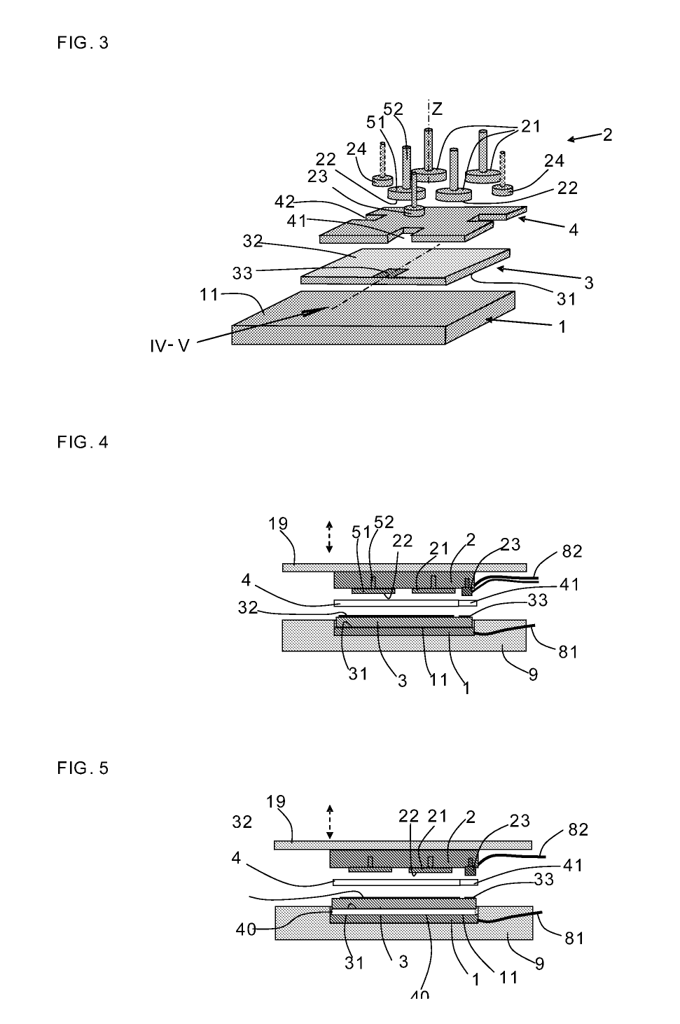

In the shown example of FIG. 2, the first contact unit 1 has a flat contact-surface 11, substantially parallel to a support plane P1 of a support 9 which supports the first contact unit 1. As shown in more detail in FIGS. 3 and 4, the die 3 is in contact with the contact-surface 11 over a bottom surface of the die, typically formed by a bottom surface of the substrate in and/or on which the power component has been formed.

The second contact unit 2 may be implemented in any manner suitable for the specific implementation and can be, as illustrated, rotatably mounted relative to the first contact unit 1 (and the support 9 of the first contact unit 1), swivelling around an axis X in parallel with the contact-surface 11, thanks to a complementary support 19 journaling around the support 9. However, in an alternative embodiment, the complementary support 19 and the second contact unit 2 can be also slidingly mounted on the support 9, for example using a guide-rails arrangement or otherwise be movable relative to the first contact unit 1.

As shown in FIG. 3, the second contact unit 2 comprises at least one, or several movable probes 21,23,24 also referred to as ‘pogos’. The pogos have respective tips or contact-surfaces 22 which are movable relative to a support 19, as explained below in more detail.

In the shown example, the pogos comprise bigger movable probes 21 which are slidingly mounted and extend in a direction Z, with is perpendicular to the main plane P2 of the complementary support 19. Each of the bigger movable probes 21 is biased in a direction away from the body 19 of the second contact unit 2, in this example parallel to the longitudinal direction of the probes 21, for example by an elastic member (not shown), spring or the like as known in the art. As depicted here, each of the bigger movable probes 21 comprises a substantially cylindrical contact member 51 with a substantially flat contact-surface 22 known as ‘second contact-surface 22’ herein and a guiding rod 52.

The second contact unit 2 further comprises smaller movable probes 23,24 also slidingly mounted in a similar manner. The smaller movables probes 23,24 exhibit a similar shape as described for the bigger movable probes and are biased downward in a similar manner, however they are not intended to drive a high current. In the shown example, they do not contact the protective sheath 4 and pass-through the cut-outs 41,42 to be in direct contact with a surface of the die 3.

The probes 21,23,24 are adapted to contact electrical contacts on the die 3 by moving them to appropriate positions parallel to the P2 plane and selecting an appropriate size of contact surface 22. The pressure exerted during test may be adapted by the biasing elements—positioning the contact surface 22 in Z and/or selecting an appropriate elastic member and/or adjusting the force exerted by the elastic member. The probes 21,23,24 are subsequently connected to an appropriate current or voltage source, or a diagnostic input.

In the shown example, the die 3 has a high-power semiconductor switch, formed by a MOS FET transistor. The die 3 to be tested on the test assembly A has a bottom face with a drain contact 31, a top face with a source contact 32 and a gate contact 33. The smaller movables probes 23,24 comprise a first auxiliary contact 23 intended to be connected with the gate contact 33 of the die, and at least one, preferably two second auxiliary probes 24 intended to be connected with the source contact 32. The first auxiliary contact 23 is able to supply the gate contact 33 with a control voltage. The second auxiliary probes 24 are able to sense the voltage and temperature on the source contact 32, e.g. for diagnostic purposes and can for example be connected to the sensor input 61 shown in FIG. 1.

Covering all connections with the protective sheath could cause excessive leakage currents, for example more than 1 nA, which can affect the accuracy of the testing. The cut-outs 41,42 mean that the electrically-conductive protective sheath 4 does not cover all connections. A cut-out faces each low-current or diagnostic connection, providing a high degree of insulation between the high-current connections and the low-current or diagnostic connections. Low-current connections are also considered to comprise connections where no current is flowing, such as test connections to a gate.

Making direct contact to the die 3 may also reduce measurement and testing errors by preventing any unexpected or unwanted effects, such as resistance, voltage drop, capacitive contact or parasitic capacitance.

The test is carried out to make a high current flow through the die. The current may be provided continuously, or in the form of pulses. To that end, the tester is adapted to provide a current which can be varied from 0 A to a maximum value of, for example, 50 A or more, 100 A or more, or 200 A or more. The tester may also be adapted to provide a current of, for example, 500 A or more, 1 kA or more, or 2 kA or more. In the example of FIG. 3-5, the current can e.g. flow from the source 32 contact to the drain contact 31, or from the drain contact 31 to the source 32 contact, depending on the P-type or N-type category of the FET on the die 3. For example, source to drain current may be used for a body diode test, and current from drain to source may be used for RDS-on and energy tests. The sheath 4 is interposed or ‘sandwiched’ between the source contact 32 and the bigger movable probes 21, and thus protects the contact-surface of the die—the sheath 4 avoids damages incurred by either a physical impact of the probes 21 on the contact 32 and/or current-induced damages due to peak current locations with an excessive current density on the surface of the die 3. It is noted that the sheath 4 may be replaced by a new one after a certain number of testing cycles, because some damage may occur on the sheath sheet 4 during tests.

FIG. 4 shows a more detailed schematic cross section of the example of the contactor in FIG. 3. In the shown example, the first contact-surface 11 is linked to the testing equipment (not shown) via a cable 81, whereas the second contact-surfaces 22 is also linked to the testing equipment via another cable 82, as well as the first auxiliary contact 23.

The first contact unit 1 is supported by the support 9 while the die 3 lies on, and is supported by the first contact unit 1 with the drain contact 31 formed by the bottom surface of the die being in direct contact of the first contact-surface 11. The sheath 4 is positioned between the top surface of the die 3, formed in this example by the drain contact 32 and the gate contact 33 and the second contact unit 2. When the second contact unit 2 is moved toward the first contact unit 1, the bigger movable probes 21 come in contact with the sheath 4 and start to press against the elastomeric sheet 4, which then in turn presses against the source contact 32 of the die 3. Accordingly, the current path through the die is established.

When the second contact unit 2 is moved toward the first contact unit 1 (or vice versa), the first auxiliary contact 23 become positioned to face the first cut-out 41 and passes through the cut-out coming in direct contact with the surface of the die and pressing therefore directly against the gate contact 33, without touching the sheath 4. Likewise, the second auxiliary contact 24 becomes positioned to face the second cut-out 42 and passes through the cut-out coming in direct contact with the surface of the die and pressing therefore directly against the source contact 32, without touching the sheath 4. The biasing elements already mentioned exert a sufficient pressure on each movable contact to ensure good quality contact.

Once the first contact unit 1 and the second contact unit 2 are moved towards each other to establish the current path, the current source 5 may be controlled to provide the current according to a current profile suitable for the specific test and the desired parameters of the die may be sensed and analysed.

Referring to FIG. 5, the example shown therein comprises a second electrically-conductive resilient protective sheath 40, similar to the first sheath 4 interposed between the first contact-surface 11 and the bottom surface of the die 3, in the example forming the drain contact 31. Thus, the die is protected at both the bottom surface and the top surface.

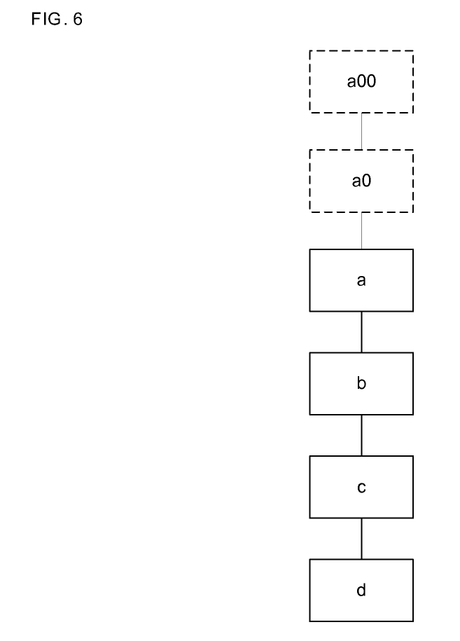

Referring to the flow chart of FIG. 6, the example shown therein comprises (letters between // referring to the blocks in FIG. 6:

/a/—placing the singulated semiconductor die 3 comprising a high-power component on a first contact unit 1,/b/—placing an electrically-conductive resilient sheath 4 on the semiconductor die 3,

/c/—causing a second contact unit 2 movably mounted relative to the first contact unit, to contact the electrically-conductive sheath 4, the bigger movable probes 21 biasing feature exerting a downward force on the sheath 4, and

/d/ —providing a high testing current, flowing between the second contact unit 2 and the semiconductor die 3 through the sheath 4, while activating the gate contact 33 with the appropriate voltage.

Prior to /a/, in block /a0/, a second electrically-conductive resilient sheath 40 may be placed on the first contact unit 1, in which case, in block /a/, the semiconductor die 3 is placed on the electrically-conductive resilient sheath 40.

In addition, prior to blocks /a/ and /a0/, in block /a00/, the method mentioned above may also comprise providing an electrically-conducting resilient sheath 4 with at least a cut-out 41 facing a contact of the die 3.

In the foregoing specification, the invention has been described with reference to specific examples of embodiments of the invention. It will, however, be evident that various modifications and changes may be made therein without departing from the broader scope of the invention as set forth in the appended claims which shall not be interpreted as being limited to the specific examples given.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Moreover, it should be noted that the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

1. Testing assembly for testing a singulated semiconductor die comprising a high-power component, said assembly comprising:
a current input connectable to a current source, for providing a high current to said high-power component;
a first contact unit, adapted to support the semiconductor die;
a second contact unit, movably mounted relative to said first contact unit;
at least an electrically-conductive resilient sheath, adapted to be sandwiched between said semiconductor die and said second contact unit when said second contact unit is brought toward the semiconductor die during a test, said sheath forming part of an electrical path from said current input through at least a part of said high-power component when thus sandwiched.

2. Testing assembly according to claim 1, comprising a signal output connectable to a signal analyzer, for receiving signals representing a sensed parameter of the high-power component sensed when said high current is provided.

3. Testing assembly according to claim 1, wherein said sheath has an electrical contact-surface with the die which is larger than the electrical contact-surface with the second contact unit.

4. Testing assembly according to claim 1, wherein said high-power component is a power FET transistor, wherein the first contact unit comprises at least a first contact-surface adapted to contact with a drain contact on said semiconductor die, and wherein the second contact unit comprises at least a second contact-surface adapted to contact with a source contact on said semiconductor die.

5. Testing assembly according to claim 1, wherein the second contact unit comprises at least a first auxiliary contact and wherein the sheath comprises a first cut-out adapted to face a contact of said semiconductor die, whereby said first auxiliary contact is adapted to directly contact said contact.

6. Testing assembly according to claim 5, wherein the second contact unit further comprises at least a second auxiliary contact, and wherein the sheath further comprises at least a corresponding additional cut-out facing the second auxiliary contact.

7. Testing assembly according to claim 4, wherein: the power FET transistor has a drain contact, a source contact and a gate contact,
the first contact-surface of the first contact unit is adapted to contact the drain contact,
the second contact-surface of the second contact unit is adapted to contact the source contact with interposition of said sheath, and
the auxiliary contact of the second contact unit is adapted to directly contact the gate contact.

8. Testing assembly according to claim 1, wherein the sheath is made of elastomeric material loaded with steel and/or copper particles.

9. Testing assembly according to claim 1, comprising a second electrically-conductive resilient sheath which is adapted to be sandwiched between said semiconductor die and said first contact unit.

10. Testing assembly according to claim 9, wherein respective surfaces of the second sheath are in direct contact with said first contact-surface of the first contact unit and a bottom surface of the die respectively.

11. Method for testing a high-power component forming part of a singulated semiconductor die, the method comprising:
placing the semiconductor die on a first contact unit having a first contact-surface,
placing an electrically-conductive resilient sheath on the semiconductor die,
causing a second contact unit movably mounted relative to said first contact unit, to contact the sheath, said second contact unit having a second contact-surface, and
providing a high testing current, flowing between the semiconductor die and the second contact unit through the sheath.

12. Method according to claim 11, comprising, prior to placing the semiconductor die on a first contact unit having a first contact-surface:
placing a second electrically-conductive resilient sheath on the first contact unit, and wherein the semiconductor die is placed on the second electrically-conductive sheath whereby the testing current flows between the first contact unit and the semiconductor die through the second sheath and between the semiconductor die and the second contact unit through the sheath.

13. Method according to claim 11, comprising, prior to placing the semiconductor die on a first contact unit having a first contact-surface:
providing a sheath and forming it to the surface of a singulated semiconductor die, with at least a cutout facing a gate contact of said semiconductor die.

14. An electrically-conductive resilient sheath adapted for a testing assembly as claimed in claim 1.

15. A testing assembly comprising:
an electrically-conductive resilient sheath as claimed in claim 14, and
a singulated semiconductor die comprising a power component.
